(19) United States
(12) Patent Application Publication
(10) Pub. No.: US 2014/0360558 A1
(43) Pub. Date: Dec. 11, 2014

(54) Pivot Framing System For Dual Glass Photovoltaic Modules

(71) Applicant: Zep Solar LLC, San Rafael, CA (US)

(72) Inventors: Jack Raymond West, San Rafael, CA (US); Nathaniel Taylor Coleman, San Rafael, CA (US)

(21) Appl. No.: 14/299,034

(22) Filed: Jun. 9, 2014

Related U.S. Application Data
(60) Provisional application No. 61/832,219, filed on Jun. 7, 2013.

(51) Int. Cl. H01L 31/042

(52) U.S. Cl. CPC H01L 31/0424
USPC 136/251

(57) ABSTRACT

A photovoltaic module assembly in which frame members are affixed by sealant onto opposite bottom edges of a dual glass photovoltaic laminate to provide a module combining the strength advantages of framed modules with the advantages of frameless dual glass photovoltaic modules.

### TECHNICAL FIELD

The present invention relates to photovoltaic module frames.

### RELATED APPLICATION

The present invention claims priority to US. Provisional Patent Application Ser. No. 61/832,219, entitled “Photovoltaic Module Frame And Method Of Construction”, filed Jun. 7, 2013, the full disclosure of which is incorporated by reference herein in its entirety.

### BACKGROUND OF THE INVENTION

Dual glass photovoltaic modules use a heat-strengthened glass layer on the back of the module, thereby replacing the conventional plastic backsheet typically found on solar modules. One advantage of dual glass modules is that they resist degradation over time. Specifically, dual glass modules are especially well adapted to resist high temperatures and high humidity environments. Unfortunately, dual glass modules are also typically more expensive and heavier than conventional modules. These factors have tended to limit their acceptance in the marketplace.

Since dual glass modules do not use frames, another disadvantage is that they are more easily subject to warping (and thus cracking) as the loads passing therethrough are not compensated for by any attached frames surrounding the module cells.

What is instead desired is a system that combines the efficiency and degradation-resistance advantages of dual glass photovoltaic modules with the structural (i.e.: frame supporting loads) advantages of more traditional framed modules. As will be shown, the present invention provides such a system.

In addition, the present invention provides an excellent pivot locking frame-type system for handling and quickly installing arrays of dual glass modules. Furthermore, the present invention provides an excellent quick and easy grounding system for arrays of dual glass modules.

### SUMMARY OF THE INVENTION

The present system provides a photovoltaic module assembly in which frame members are affixed by sealant onto opposite bottom edges of a dual glass photovoltaic laminate. This assembly provides a module combining the strength advantages of framed modules with the advantages of frameless dual glass photovoltaic modules.

By using two frame members, the system increases structural support (as compared to frameless dual glass modules), while still reducing frame material (thereby reducing overall frame weight) since frame members need only be positioned on two of the four sides of the module. Moreover, in optional embodiments, the two frame member need not extend the full length of the sides of the modules. For example, the two frame members may each only run along partial sections of the sides of the module. For example, the frame members may only be located at the corner ends of the modules, if desired. This further reduces the amount of framing material used.

An additional advantage of a preferred embodiment of the present frame members is that they can be dimensioned for connectors (and mounting supports such as levelling feet) to be pivot locked therein. This makes array setup both fast and easy. Yet another advantage of such frame member structures are that they provide a system for module-to-module grounding using these same connectors.

### BRIEF DESCRIPTION OF THE DRAWINGS

FIG. 1A is a perspective view of the present system.

FIG. 1B is an enlarged perspective view of a corner of the system seen in FIG. 1A.

FIG. 2A is a perspective view of a photovoltaic module frame according to the present system.

FIG. 2B is a side elevation view corresponding to FIG. 2A.

FIG. 3 is a side elevation view corresponding to FIG. 1B.

FIG. 4 is a side elevation view of two of the dual glass modules of FIG. 3 connected together.

### DETAILED DESCRIPTION OF THE DRAWINGS

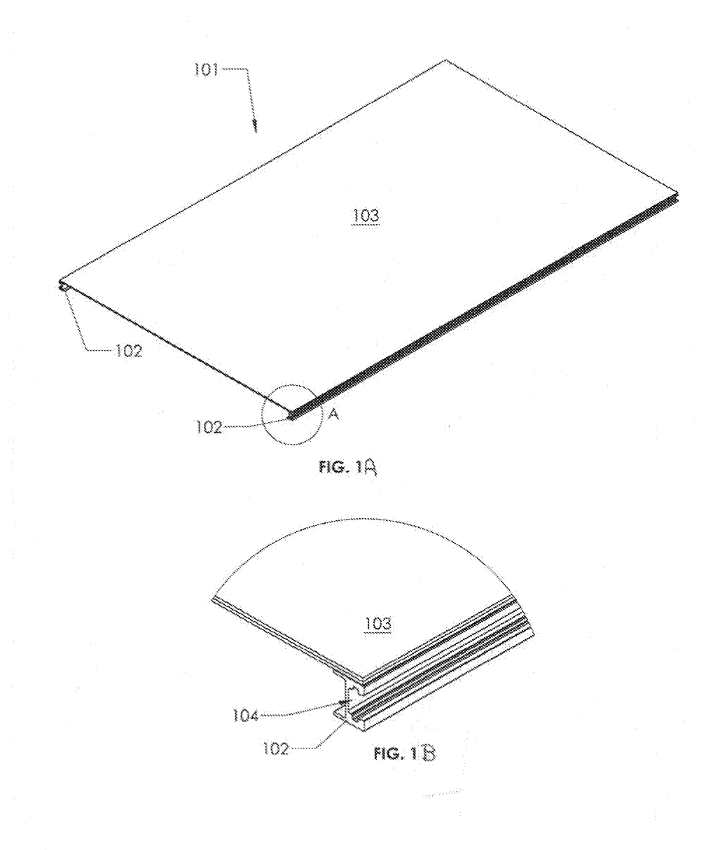

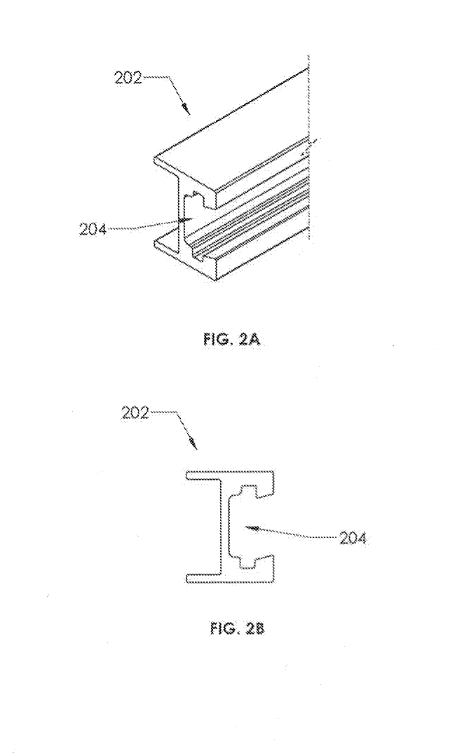

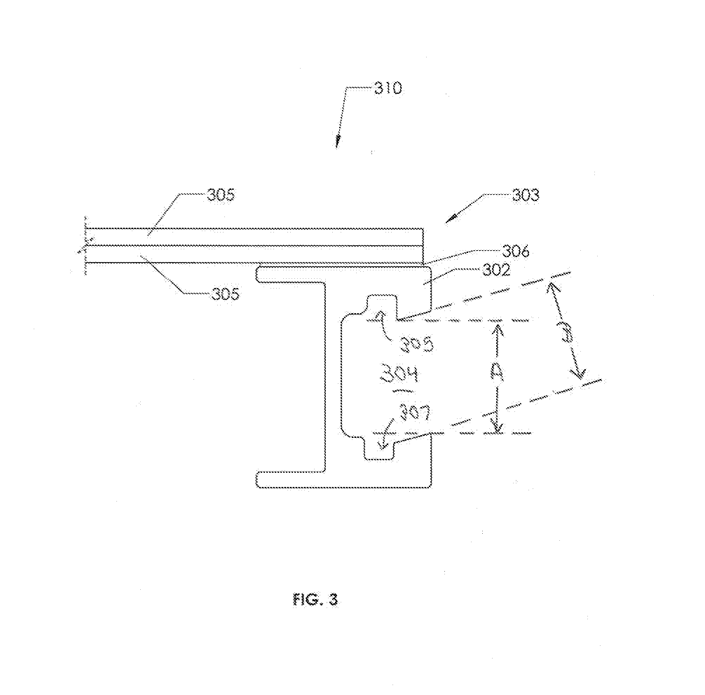

FIG. 1A is a perspective view of a preferred embodiment of the present system, and FIG. 1B is an enlarged perspective view of a corner of the system. FIG. 3 is a side elevation view corresponding to FIG. 1B. FIG. 2A and FIG. 2B are perspective and side elevation views of the photovoltaic module frame according to the present system.

FIGS. 1A and 1B show a photovoltaic module 101 with frame members 102 located on opposing (long) sides of a photovoltaic module. However, it is to be understood that frame members 102 may instead be situated on the two short sides of the module, or even all four sides, or three sides of the module, all keeping within the scope of the present invention. Rectangular laminate 103 contains the photovoltaic cells that generate electricity when exposed to light.

FIGS. 2A and 2B shows a profile of a preferred embodiment of frame member 202 that may be constructed of various materials. Preferred embodiments of this frame profile are constructed of extruded aluminum. The frame member profile may contain a groove 204 that is capable of receiving portions of mounting and bonding hardware used for the installation and grounding of conductive items in photovoltaic arrays, as will be explained.

FIG. 3 shows an assembly 310 containing the frame 302, a laminate 303 comprised in this embodiment and without limitation of two pieces of glass 305 that may be adhered to frame member 302 using a layer of sealant 306. Thus, as can be seen, the present system provides a photovoltaic module assembly, comprising: (a) a dual glass photovoltaic laminate; and (b) two frame members, each frame member extending along an opposite side of the photovoltaic laminate, wherein each frame member is adhered with a sealant to an edge of the dual glass photovoltaic laminate.

It is to be understood, however, that other forms of adherence such as commonly available frame tapes may instead be used. Moreover, the present system can optionally be used with more traditional laminate constructions comprised of a single piece of glass and a commonly available back sheet material, such as Tedlar® by way of example and without limitation.

Advantages of using the present system of a pair of frame members 102 adhered by sealant 306 onto the bottom edges of a dual glass laminate 103 or 303 may include, but are not limited to, the following: (a) Reduction in frame material usage (since the frame members 102, 202, 302 need only be on two sides or portions of two sides of the laminate 103, 303); (b) Providing structural support to the laminate construction (since the frame members 102, 202, 302 will resist warping of the laminate and will distribute loads therethrough); (c) Allowing for ease of movement and installation of module 101 (since the frame members will give the installers a hand gripping surface); (d) Allowing for the mounting of module and array level electronic devices and accessories including, but not limited to, microinverters, power optimizers, junction boxes, wire routing devices, and module skirts/deflectors/screens (since these electronic devices can be mounted directly to the frame members 102, 202, 302 prior to, or during, installation; (e) Providing protection of the glass portion of laminate from damage during transport, movement to roof/structure and during installation; and (f) Providing protection of j-box, providing protection of cables from damage during transport and movement to roof/structure and during installation.

Optional embodiments of photovoltaic module 101 depicted in FIG. 1 may include, but are not limited to embodiments with short sections of frame 102 containing the groove 104 that are affixed only to the end portions and/or corners of the laminate 103 on the long and/or short sides of the module. This optional embodiment would still allow for the interlocking of adjacent modules using ancillary hardware in order to facilitate a continuous beam for increased structural capacity of arrays.

In addition, the present system also encompasses the addition of short sections of frame members 102 containing groove 104 via a clamping device, adhesives or other mechanical means of attachment to any portion of the laminate edge can allow for the installation of supports that connect to an underlying structure in order to vary the unsupported span sections of the module to facilitate site based loading pressures due to wind, snow and other natural forces.

Optionally as well, the short sections of frame members 102 containing groove 104 containing the clamping device in the upper portion of the frame may accept the laminate and allow for positioning anywhere along the laminate edge in the field during the installation of the modules to a roof or other structure. In a preferred embodiment, the laminate accepting clamp device may have one or two or more set screws that are used for clamping the laminate between two substantially parallel plates. A compliant material may be added to the substantially parallel plates to prevent scratching/breaking of the laminate glass during clamping. Once the desired position along the laminate edge has been achieved, the set screws may be torqued to fix it in place. The fixed section of frame containing the clamping device may then accept groove compatible type supports (i.e. the leveling foot and mounting block) in both the “Rock-in” and “Drop-in” motions and methods of installation that have been disclosed in other granted and pending patents assigned to Zep Solar, LLC of San Rafael, Calif.

For example, as seen in FIG. 3, groove 304 is dimensioned for a connector to pivot lock therein. Importantly, the width of the opening in groove 304 is greatest when measured at an angle to the plane of the photovoltaic laminate. Specifically, this means that distance “A” (measured between two planes parallel to the laminate) is slightly less than distance “B” (measured between two parallel planes that are both at an angle to the laminate). As a result, the angled path defined by the planes spaced apart by distance “B” is the widest opening into the groove 304. As a result, a leveling foot or mounting bracket or coupling can be inserted at an angle into groove 304, and then rotated down to snap into a final locked position parallel to the plane of laminate 303. As can also be seen, side groove 303 preferably includes a mid-portion with an upper recess 305 and a lower recess 307 defining a key slot.

The advantage of the framing system shown in FIG. 3 is that the novel shape of groove 304 can be used to provide easy pivot locking of various connectors (and panel-to-panel grounding elements) therein. As a result, an easy to handle and position assembly 310 is provided, offering a module combining the strength advantages of framed modules with the advantages of frameless dual glass photovoltaic modules.

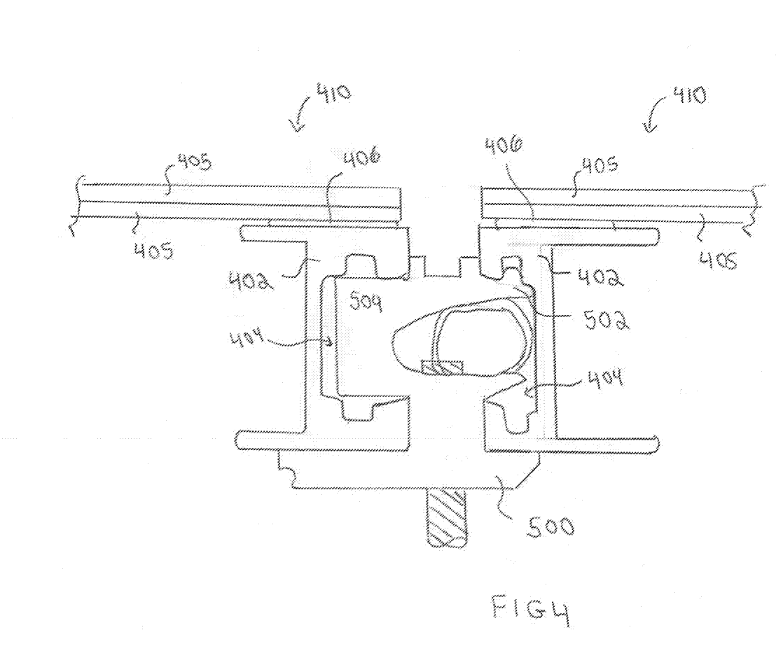

For example, as seen in FIG. 4, a ZEP “Rockit” connector 500 is shown linking together two assemblies 410. In this arrangement, a key portion 502 is received into one assembly's groove 404 while an opposite tongue portion 504 is received into the other assembly's groove 404.

What is claimed is:

1. A photovoltaic module assembly, comprising:
(a) a dual glass photovoltaic laminate; and
(b) two frame members, each frame member extending along an opposite side of the photovoltaic laminate, wherein each frame member is adhered with a sealant to an edge of the dual glass photovoltaic laminate, and wherein each frame member has a side groove dimensioned for a connector to pivot lock therein.

2. The assembly of claim 1, wherein the assembly comprises only the two frame members with no frame members connected to a third and a fourth side of the dual glass photovoltaic laminate.

3. The assembly of claim 1, wherein the two frame members extend fully along the opposite sides of the photovoltaic laminate.

4. The assembly of claim 1, wherein the two frame members extend only partially along the opposite sides of the photovoltaic laminate.

5. The assembly of claim 1, wherein the width of the opening in the side groove is greatest when measured at an angle to the plane of the photovoltaic laminate.

6. The assembly of claim 1, wherein the outer opening of the side groove is angled with respect to the plane of the photovoltaic laminate.

7. The assembly of claim 1, wherein the outer opening of the side groove is defined by a pair of generally parallel sloped upper and lower surfaces that are angled with respect to the plane of the photovoltaic laminate.

8. The assembly of claim 1, wherein the side groove has a mid-portion with an upper recess and a lower recess defining a key slot.

9. The assembly of claim 1, wherein the two frame members are made of extruded aluminum.
